(19) United States
(12) Patent Application Publication
(10) Pub. No.: US 2019/0143405 A1
(43) Pub. Date: May 16, 2019

(54) Methods of Fabricating Conductive Thick-Film Pastes of Base Metals with High Conductivity Achieved

(71) Applicant: National Cheng Kung University, Tainan (TW)

(72) Inventor: Wen-Hsi Lee, Tainan (TW)

(21) Appl. No.: 15/810,417

(22) Filed: Nov. 13, 2017

(51) Int. Cl. B22F 1/02; H05K 3/12

(52) U.S. Cl. CPC B22F 1/025; H05K 3/1291; H01L 21/4846; B22F 2301/10; B22F 2301/052

(57) ABSTRACT

Methods are provided to fabricate thick-film pastes with low cost by using base metals. The pastes achieve high conductivity and are sintered at low or high temperatures in the air. Therein, an aluminum powder is cladded with copper particles in a thickness of tens of nanometers to several microns for obtaining a copper-clad aluminum paste with high conductivity. The copper particles can be reduced with silver. A nanoscale silver-clad aluminum powder has a sintering temperature down to about 350 celsius degrees. Hence, the PCB electroplating copper electrode can be replaced to expel the expensive yellow-light development. The problem of solution pollution during electroplating is solved. Nevertheless, the expensive metal silver electrode used in screen printing can be replaced. The problem of the expensive required reduction atmosphere in screen printing can be solved as well. Thus, the material cost is significantly reduced for PCB substrates or ceramic substrates.

### TECHNICAL FIELD OF THE INVENTION

The present invention relates to fabricating thick-film conductive pastes; more particularly, to using thick-film materials of base metals for achieving high conductivity, where aluminum particles cladded with silver or copper are sintered at a low temperature in the air to obtain base-metal conductive pastes with high conductivity.

### DESCRIPTION OF THE RELATED ARTS

Regarding conductivity of metals, silver is the best, followed by copper, gold and aluminum. However, the price of silver is higher than copper and the price of the third metal gold is higher than silver and copper. Hence the first two metals—silver and copper—are taken as the most suitable materials for wires. Copper is a more popular material for more than a decade because copper has low cost, low resistivity, good adhesion to substrate, excellent welding and erosion resistance, low diffusivity, and high resistance to electromigration. However, copper has a strong oxidation potential energy. Its fabrication and applications are prone to oxidation to cause decrease in conductivity. Therefore, a nitrogen atmosphere having an oxygen partial pressure below 10 ppm is in need during the fabrication. In addition, the conductivity of a copper electrode will increase following the rise of the sintering temperature.

Table 1 shows the characteristics and applications of conductive thick-film pastes of metallic silver and metallic copper sintered at high and low temperatures. In the case of the general thick-film metallic copper pastes, the metallic copper particles are liable to be oxidized in the air regardless of the sintering temperature. Therefore, they must be sintered in a reduction atmosphere to avoid the problem of copper oxidation and have to be sintered at a high temperature for achieving high conductivity. Although the general thick-film silver pastes can be sintered in the air to get high conductivity, silver as a precious metal is expensive and, not to mention, unstable. If the copper and silver pastes are sintered at a low temperature, a drawback exists in that the conductivity will be greatly reduced due to the partially-contained nonconductive resin.

TABLE 1

| | High- | Low- | High- | Low- |
|---|---|---|---|---|
| | temperature | temperature | temperature | temperature |
| | high- | low- | high- | low- |
| | conductivity | conductivity | conductivity | conductivity |
| | silver paste | silver paste | copper paste | copper paste |
| Sintering | 800~900° C. | 150~250° C. | 800~900° C. | 150~250° C. |
| temperature | | | | |
| Sintering | Air | Air | Nitrogen | Nitrogen |
| atmosphere | | | | |
| Conductivity | 10⁻⁶ Ω · cm | 10⁻⁵ Ω · cm | 10⁻⁶ Ω · cm | 10⁻⁵ Ω · cm |
| Procedure | High | Low | High | High |
| cost | | | | |
| Material cost | High | High | High | Low |
| Main | Passive | Membrane | Passive | Membrane |
| applications | component | switch | component | switch |
| | Silicon- | Touch panel | Silicon-based | Touch panel |
| | based | RFID | solar cell | |
| | solar cell | | LED cooling | |
| | LED cooling | | substrate | |
| | substrate | | | |

Because silver is a precious metal, the material cost will become high if a powder of the precious metal silver is used as the main conductor material. It is also vulnerable to the impact of price fluctuations. For reducing the material cost, copper is chosen as the material generally used. But, since the copper paste has to be sintered in a reduction atmosphere, the procedure cost is bound to increase. In addition, the copper or silver paste sintered at a low temperature would use polymer resin as the binder, which leads to a shortcoming of low conductivity. The fourth metal aluminum is the second best choice. Although having a lower material cost and being a high-conductivity metal, aluminum metal is easy to form a thin layer of aluminum oxide on surface to avoid further oxidation. It leads to a problem that the layer of aluminum oxide on surface will hinder the contact between the metallic aluminum balls. As a result, the thick-film aluminum paste has conductivity much lower than the general thick-film silver or copper pastes. Hence, the prior arts do not fulfill all users' requests on actual use.

### SUMMARY OF THE INVENTION

The main purpose of the present invention is to provide thick-film conductive pastes of base metals for achieving high conductivity, where aluminum particles cladded with silver or copper are sintered at a low temperature in the air to obtain the base-metal thick-film conductive pastes with high conductivity.

Another purpose of the present invention is to sintering the aluminum particles cladded with silver or copper at a low or high temperature in the air for obtaining the base-metal thick-film conductive pastes with high conductivity, where the base metal aluminum has a highest reduction potential, copper follows and the noble metal silver has the lowest reduction potential; an aluminum powder is cladded with copper particles in a thickness of tens of nanometers to several microns for obtaining a copper-clad aluminum powder with high conductivity; silver can be used to reduce copper particles for cladding silver particles in a thickness of tens of nanometers to several microns on the surface of aluminum particles to obtain a silver-clad aluminum powder with high conductivity; if nano silver-clad aluminum powder is obtained, the sintering temperature can be lowered down to about 350° C.; and the material cost is significantly reduced for PCB substrates or ceramic substrates.

To achieve the above purposes, the present invention is a method of fabricating a conductive thick-film paste of a base metal with high conductivity achieved. A first preferred embodiment comprises steps of: (a1) dissolving a metallic copper powder to obtain a metallic copper solution; (b1) mixing a pretreated metallic aluminum powder with the metallic copper solution to obtain a first metals-mixed solution, where a chemical displacement reaction is processed in the first metal mixed solution; free copper ions in the metallic copper solution move to the surface of the pretreated metallic aluminum powder to obtain a layer of copper; and the layer of copper has a cladding thickness between tens of nanometers and several micrometers; (c1) after filtering and drying the first metals-mixed solution, obtaining an aluminum powder cladded with copper; and (d1) sintering the aluminum powder cladded with copper in the air to obtain a copper-clad aluminum thick-film paste. A second preferred embodiment comprises steps of: (a2) processing a corrosive wash to an aluminum powder cladded with copper; (b2) obtaining the washed aluminum powder cladded with copper to be dissolved in ethylene glycol to obtain a copper-clad aluminum powder solution, and obtaining a metallic silver powder to be dissolved in ethylene glycol to obtain a metallic silver solution; (c2) mixing the copper-clad aluminum powder solution with the metallic silver solution to obtain a second metals-mixed solution, where a chemical displacement reaction is processed in the second metals-mixed solution; free silver ions in the metallic silver solution move to surface of the washed aluminum powder cladded with copper to process reduction to obtain a layer of silver selected from a group consisting of micron silver and nano silver; and the layer of silver has a cladding thickness between tens of nanometers and several micrometers; (d2) after filtering and drying the second metals-mixed solution, obtaining an aluminum powder cladded with silver selected from a group consisting of micron silver and nano silver; and (e2) sintering the aluminum powder cladded with silver selected from a group consisting of micron silver and nano silver in the air to obtain a silver-clad aluminum thick-film paste. Accordingly, novel methods of fabricating conductive thick-film pastes of base metals with high conductivity achieved are obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the view showing the aluminum powders cladded with copper and silver according to the present invention as compared with the aluminum powder uncladded;

FIG. 2A-FIG. 2C are the views showing the thermal analysis of the aluminum powders cladded with copper and silver as compared with the aluminum powder uncladded, separately;

FIG. 3 is the flow view showing the fabrication of the aluminum powder cladded with copper;

FIG. 4 is the scanning electron microscopy (SEM) image showing the surface of the metallic aluminum powder cladded with copper;

FIG. 5 is the flow view showing the fabrication of the aluminum powder cladded with silver; and

FIG. 6 is the SEM image showing the surface of the metallic aluminum powder cladded with silver.

### DESCRIPTION OF THE PREFERRED EMBODIMENT

The following description of the preferred embodiment is provided to understand the features and the structures of the present invention.

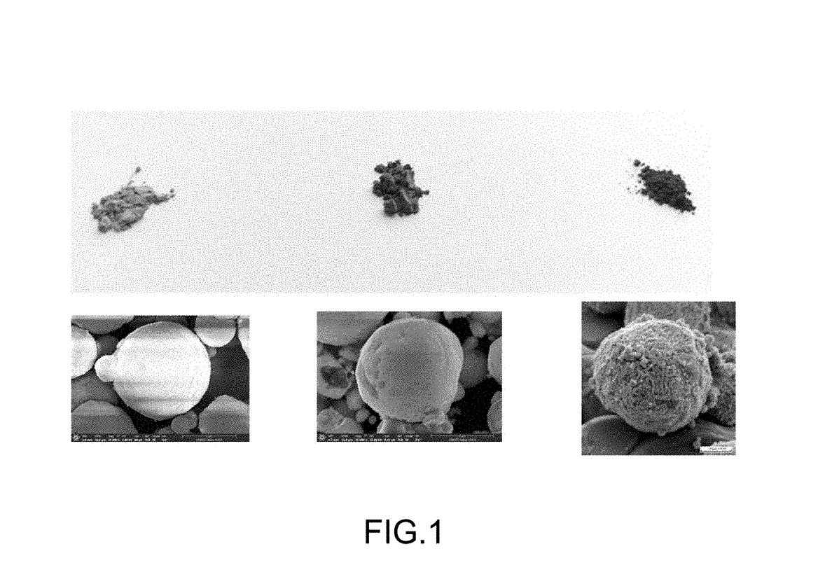

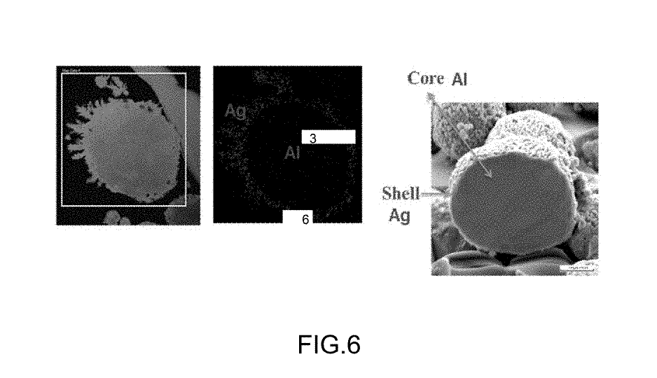

Please refer to FIG. 1˜FIG. 6, which are a view showing aluminum powders cladded with copper and silver according to the present invention as compared with an aluminum powder uncladded; views showing thermal analysis of the aluminum powders cladded with copper and silver as compared with the aluminum powder uncladded, separately; a flow view showing the fabrication of the aluminum powder cladded with copper; a SEM image showing the surface of a metallic aluminum powder cladded with copper; a flow view showing the fabrication of the aluminum powder cladded with silver; and a SEM image showing the surface of a metallic aluminum powder cladded with silver. As shown in the figures, the present invention is a method of fabricating conductive thick-film pastes of base metals with high conductivity achieved, where aluminum particles cladded with silver or copper are sintered in the air even at a low temperature to obtain high-conductivity base-metal pastes.

For improving the conductivities of thick-film metallic aluminum pastes, the present invention clads the surfaces of aluminum metal balls with high-conductivity copper or silver, where the aluminum oxide can be prevented from being formed on the surface of the metallic aluminum powders and the high conductivity of the metallic aluminum powders cladded with silver or copper can be maintained. In FIG. 1, the appearances of the aluminum powders cladded with copper and silver are shown. At first, powders are pressed at a high pressure to form ingots of silver, aluminum, aluminum cladded with copper, and aluminum cladded with silver, where each ingot has a diameter of 1 centimeter and a thickness of 3.5 millimeter. The resistance values are measured as shown in Table 2. Obviously, because aluminum powder has a barrier layer of oxide on surface to prevent metallic aluminum powder from touching aluminum powder, the ingot of aluminum has a resistance value 50 to 100 times of that of the ingot of silver. However, through cladding aluminum with a layer of copper or silver on surface, the resistance value of the ingot of aluminum cladded with copper is very close to that of the ingot of aluminum cladded with silver. It means that the contact resistances of the aluminum powders cladded with copper and silver can be greatly improved.

TABLE 2

| | | | | |
|---|---|---|---|---|
| Diameter 1 cm | Silver | Aluminum | Copper-clad | Silver-clad |
| Thickness | ingot | ingot | aluminum | aluminum |
| 3.5 mm | | | ingot | ingot |
| Resistance | 0.04 mΩ | 1~2 mΩ | 0.08 mΩ | 0.05 mΩ |

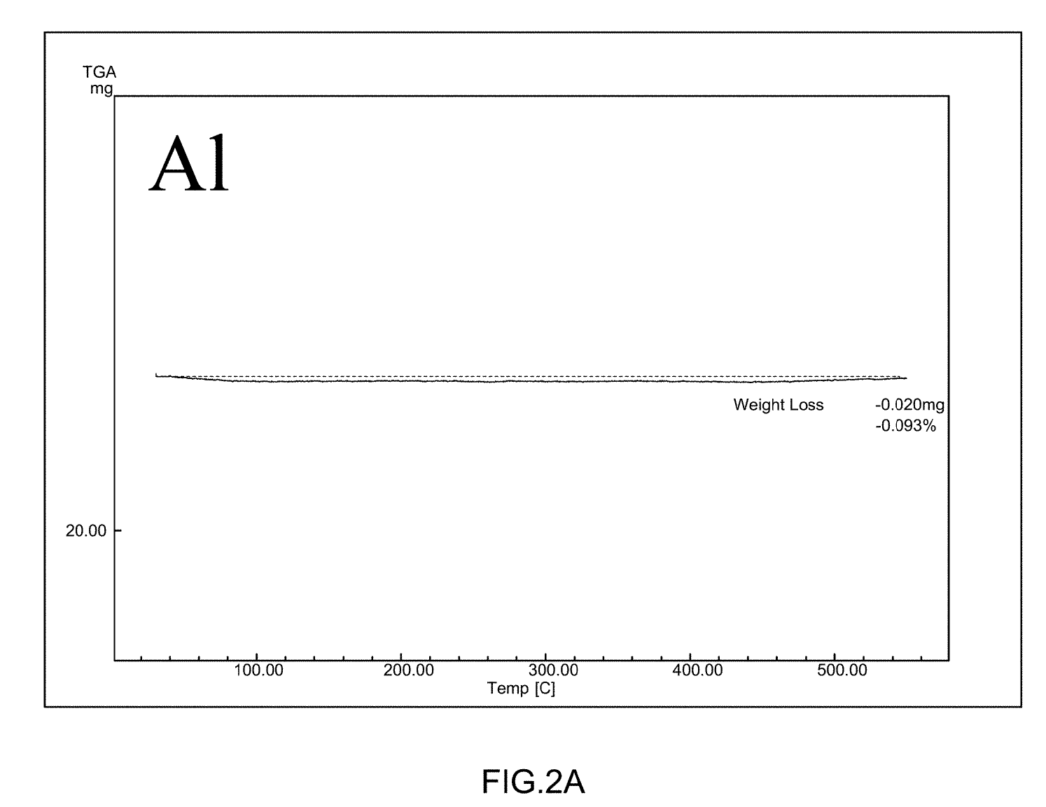

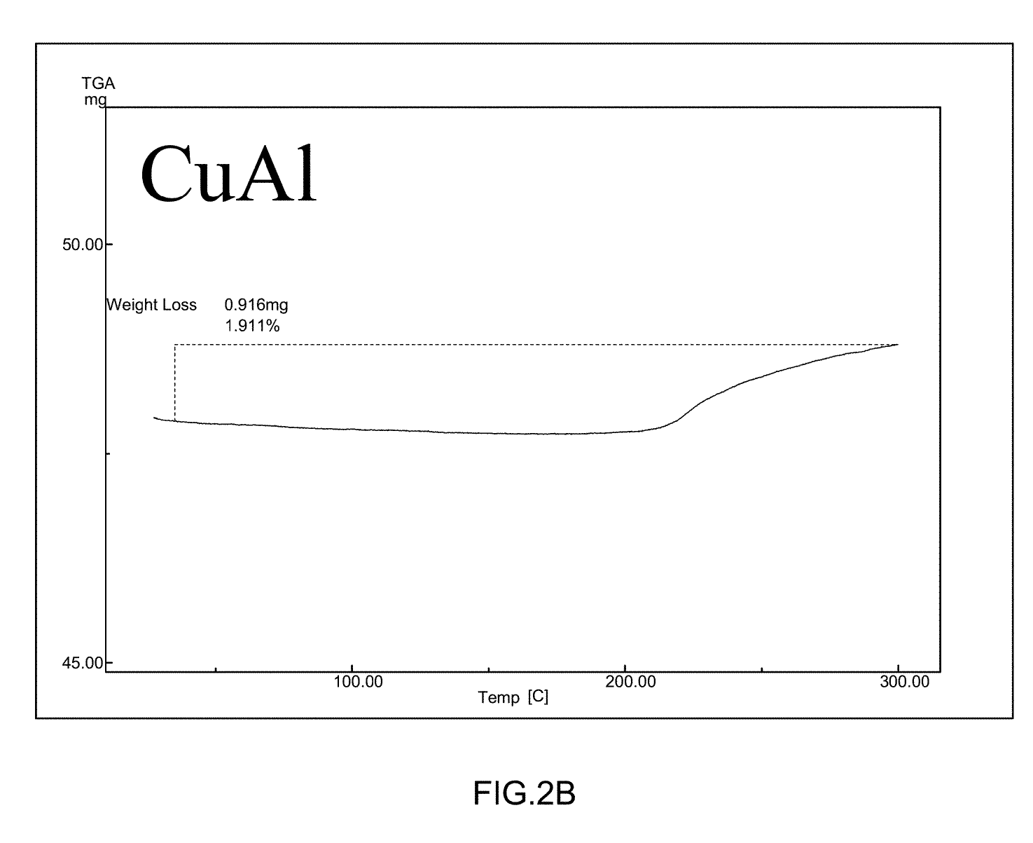

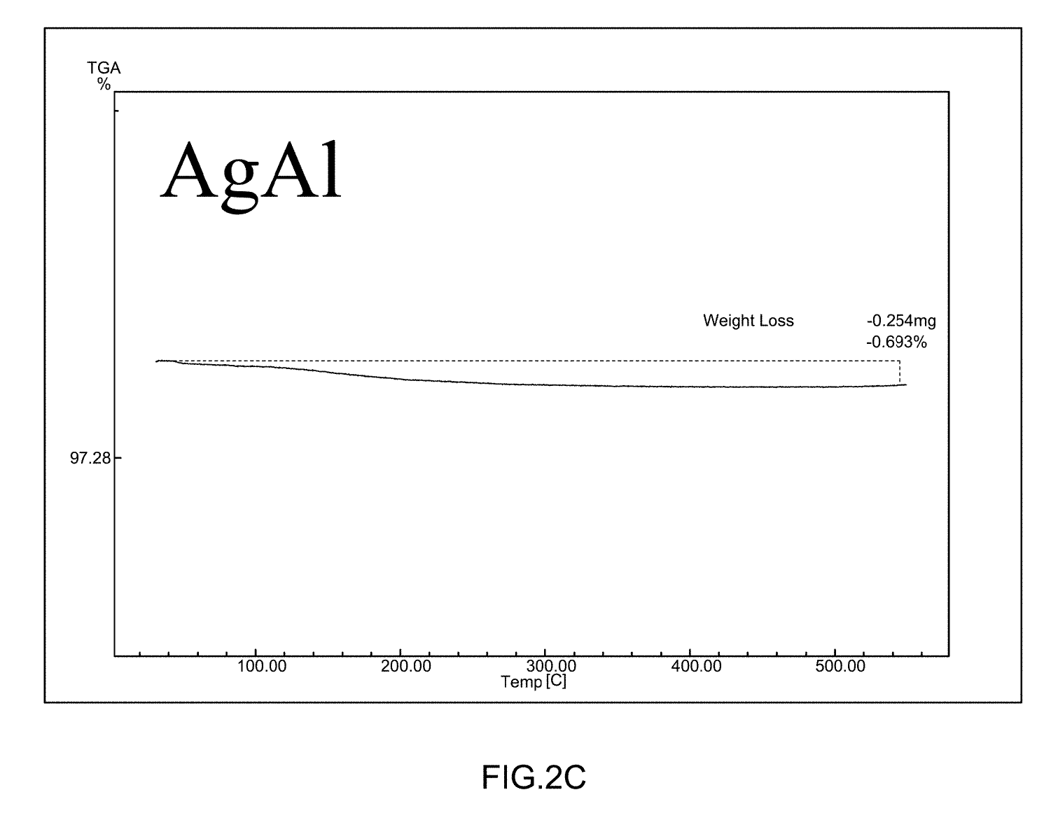

In FIG. 2A˜FIG. 2C, a thermal analysis of the aluminum powder uncladded as compared with the aluminum powders cladded with copper and silver is shown. Therein, because the metallic aluminum powder is protected by aluminum oxide on surface to prevent oxidation, its weight is not increased even when the temperature continuously climbs. Concerning the aluminum powder cladded with copper, its weight is increased when the temperature rises above 220 celsius degrees (° C.). It means that the oxidation occurs. As for the aluminum powder cladded with silver, the aluminum surface is protected by the layer of silver so that the oxidation does not occur when the temperature rises. The present invention uses a low-cost chemical displacement reaction for cladding copper or silver on the metallic aluminum powder, where the sequence of metal reduction potential is aluminum>copper>silver.

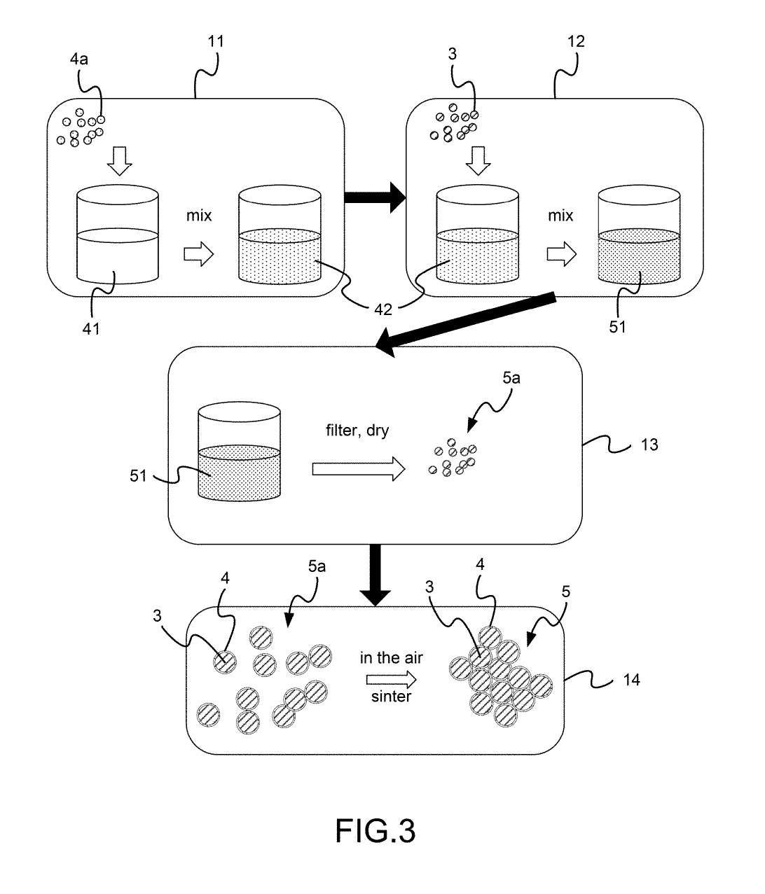

For fabricating an aluminum powder cladded with copper, a flow view of a first preferred embodiment according to the present invention is shown in FIG. 3, comprising the following steps:

(a1) Forming metallic copper solution 11: A metallic copper powder, such as a copper sulfate powder 4a, is dissolved and mixed in a solution 41 to form a copper sulfate solution 42.

(b1) Forming copper layer on powder surface 12: A pretreated metallic aluminum powder 3 and the copper sulfate solution 42 are mixed to form a first metals-mixed solution 51. The first metals-mixed solution 51 is subjected to a chemical displacement reaction. The chemical displacement reaction between aluminum and copper is happened in the first metals-mixed solution 51 because aluminum metal has a higher activity than copper metal. Aluminum particles are separated into the first metal mixed solution 51 while copper ions freed from copper metal are precipitated on the outer surface of the aluminum particles. In the first preferred embodiment, the chemical displacement reaction is processed at a desired temperature for a desired time to allow the copper ions freed from copper metal to move toward the surface of the pretreated metallic aluminum powder 3 and form a layer of copper 4 on the surface of the pretreated metallic aluminum powder 3.

(c1) Obtaining copper-clad powder 13: After filtering and drying the first metals-mixed solution 51, an aluminum powder cladded with copper 5a is obtained.

(d1) Obtaining copper-clad paste 14: The aluminum powder cladded with copper 5a is sintered in the air to obtain a copper-clad aluminum thick-film paste 5. Therein, the layer of copper 4 on the copper-clad aluminum thick-film paste 5 has a cladding thickness between tens of nanometers and several micrometers.

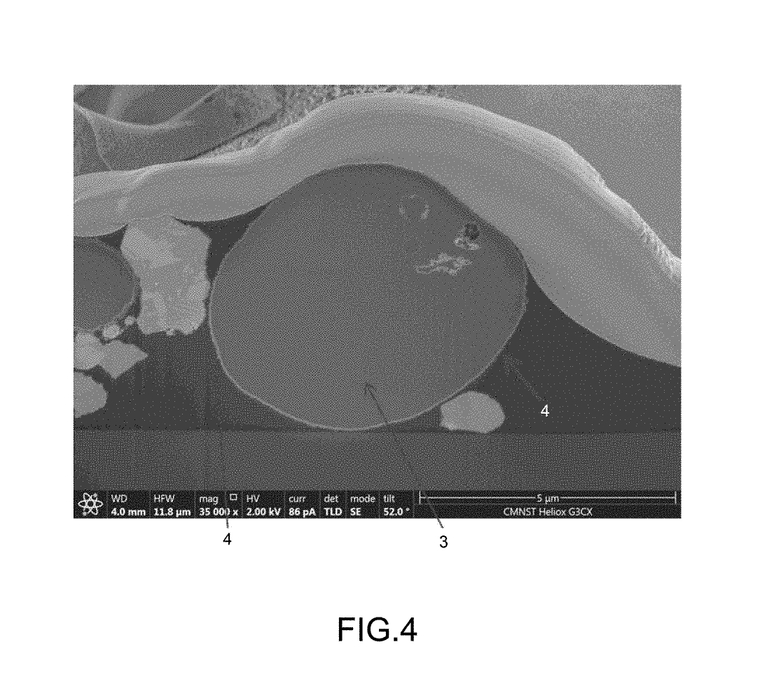

In the first preferred embodiment, the present invention uses a galvanic displacement reaction to fabricate an aluminum powder cladded with copper, where the general metallic copper powder is replaced by a thick-film paste which achieves high conductivity and is sintered under a high or low temperature. As shown in the flow view in FIG. 3, the layer of copper 4 formed on surface is used as a binder for contacting the metallic aluminum powder 3 to reduce the contact resistance of the metallic aluminum powder 3. As shown in FIG. 4, the layer of copper 4 has a cladding thickness about 200˜1000 nanometers (nm) and is uniformly cladded on the surface of the metallic aluminum powder 3.

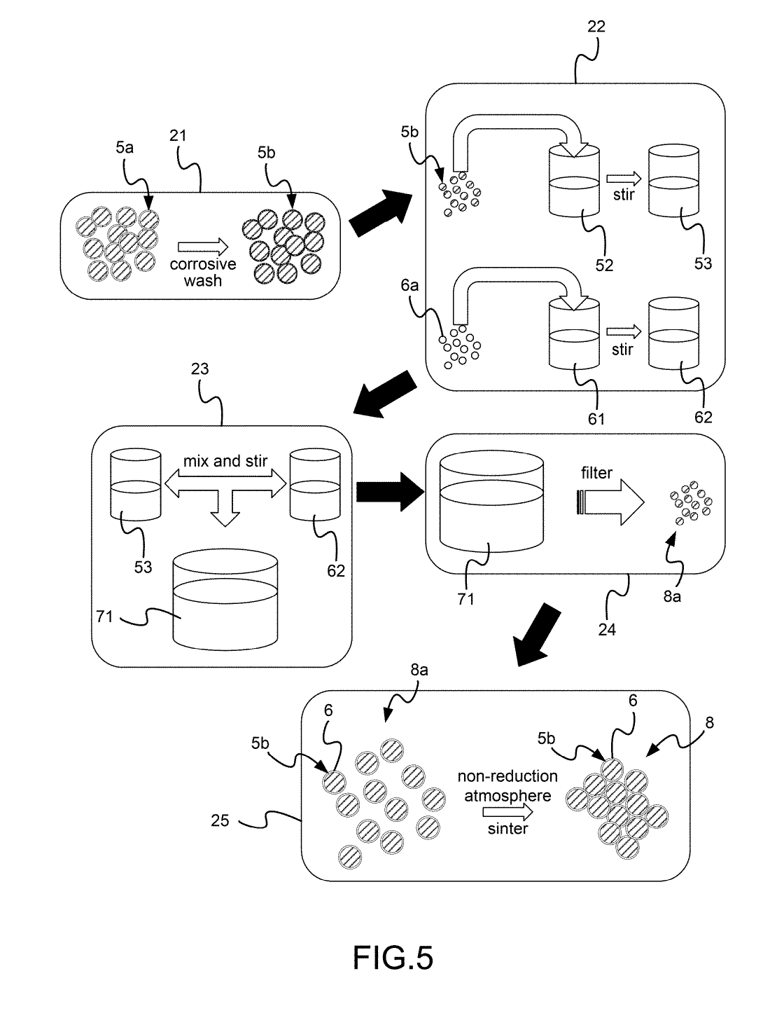

For fabricating an aluminum powder cladded with silver, a flow view of a second preferred embodiment according to the present invention is shown in FIG. 5, comprising the following steps:

(a2) Washing copper-clad powder 21: The aluminum powder cladded with copper 5a fabricated in the first preferred embodiment is processed through corrosive wash.

(b2) Forming solutions of copper-clad powder and silver nitrate 22: The washed aluminum powder cladded with copper 5b is dissolved in ethylene glycol 52 to form a copper-clad aluminum powder solution 53. Then, a metallic silver powder, such as a silver nitrate powder 6a, is dissolved in ethylene glycol 61 to form a silver nitrate solution 62.

(c2) Forming silver layer on powder surface 23: The copper-clad aluminum powder solution 53 and the silver nitrate solution 62 are mixed to form a second metals-mixed solution 71. The second metal mixed solution 71 is subjected to a chemical displacement reaction. The chemical displacement reaction is happened between copper and silver in the second metal mixed solution 71 because copper metal has a higher activity than silver metal. Copper particles are separated into the second metal mixed solution 71 and silver ions are precipitated to be grown on the outer surface of aluminum particles cladded with copper. In the present invention, the chemical displacement reaction is processed at a desired temperature for a desired time to allow the silver ions freed from silver metal to move toward the surface of the washed aluminum powder cladded with copper 5b and form a layer of micron or nano silver 6 on the surface of the washed aluminum powder cladded with copper 5b.

(d2) Obtaining silver-clad powder 24: After filtering and drying the second metals-mixed solution 71, an aluminum powder cladded with micron or nano silver 8a is obtained.

(e2) Obtaining silver-clad paste 25: The aluminum powder cladded with micron or nano silver 8a is sintered in the air to obtain a micron or nano silver-clad aluminum thick-film paste 8. Therein, the layer of micron or nano silver 6 has a cladding thickness between tens of nanometers and several micrometers.

In the second preferred embodiment, the present invention uses a galvanic displacement reaction to fabricate a silver-clad aluminum powder for obtaining a conductive paste which achieves high conductivity and is fabricated under a high or low temperature. As shown in a flow view in FIG. 5, the layer of micron or nano silver 6 formed on surface is used as a binder for contacting the metallic aluminum powder 3 to reduce the contact resistance of the metallic aluminum powder 3. As shown in FIG. 6, the layer of silver 6 has a cladding thickness about 200˜1000 nm and is uniformly cladded on the surface of the metallic aluminum powder 3.

According to the above discussion, the reduction potential of copper is lower than that of aluminum; and, as the aluminum oxide on the surface of the metallic aluminum powder is removed through pretreatment and copper is precipitated through the chemical replacement reaction to be grown on the aluminum particles, the conductive paste fabricated with the aluminum powder cladded with copper obtains the following advantages:

1. The overall conductivity increases.

2. The internal aluminum does not form aluminum oxide on surface.

3. The cost is lower than that of copper alone used originally.

4. Electromigration resistance is good.

5. After aluminum is covered by copper, the mixed low-temperature resin can be replaced by the low-temperature copper paste having resin for being sintered at a low temperature in the air.

On the other hand, because the reduction potential of silver is lower than that of copper, silver can be precipitated on the surface of the metallic aluminum powder through a chemical replacement reaction with balls of aluminum cladded with copper for forming balls of aluminum cladded with silver. The conductive paste fabricated with the aluminum powder cladded with silver has the following advantages:

1. The overall conductivity increases.

2. The internal aluminum does not form aluminum oxide on the surface.

3. The cost is lower than that of silver alone original used.

4. Electromigration resistance is good.

5. After aluminum is covered by silver, the mixed low-temperature resin can be replaced by the low-temperature silver paste having resin for being sintered at a low temperature in the air; and the glass mixed can by replaced by the high-temperature thick-film silver paste for being sintered at a high temperature in the air.

In Table 3, the electrical characteristics and application fields of thick-film copper-clad aluminum pastes are shown, where the aluminum powders cladded with copper are added with resin or glass, respectively, for fabricating the copper-clad pastes to be sintered at a low temperature (<220° C.) in the air or at a high temperature in a nitrogen atmosphere. The aluminum powders cladded with copper can replace silver in the market for developing a low-temperature thick-film conductive paste. In the same way, aluminum powders cladded with silver are added with resin or glass, respectively, for fabricating the silver-clad pastes to be sintered at a low temperature or a high temperature in the air. The aluminum powders cladded with silver can replace silver in the market for developing a low-temperature thick-film conductive paste.

TABLE 3

| | 1 | 2 | 3 | 4 | 5 |
|---|---|---|---|---|---|
| Metal powder | Copper-clad | Copper-clad | Silver-clad | Silver-clad | Nano silver- |
| | aluminum | aluminum | aluminum | aluminum | clad |
| | | | | | aluminum |
| Binder | Resin | Glass | Resin | Glass | Nano silver |
| Sintering | <220° C. | <600° C. | <300° C. | <600° C. | <300° C. |
| temperature | | | | | |
| Sintering | Air | Nitrogen | Air | Air | Air |
| atmosphere | | | | | |
| Resistivity | <1 × 10⁻⁵ | <1 × 10⁻⁶ | <1 × 10⁻⁵ | <1 × 10⁻⁶ | <1 × 10⁻⁶ |
| Obtained | Low- | High- | Low- | High- | Nano silver |
| target | temperature | temperature | temperature | temperature | paste |
| | copper paste | copper | silver paste | silver paste | |
| | | paste | | | |
| Application | Membrane | Passive | Membrane | Passive | High-power |
| field | switch | component | switch | component | PCB |
| | Touch panel | Silicon- | Touch | Silicon- | Passive |
| | RFID | based solar | panel | based solar | component |
| | | cell | RFID | cell | Silicon-based |
| | | LED cooling | | LED cooling | solar cell |
| | | substrate | | substrate | LED cooling |
| | | | | | substrate |

When aluminum is cladded with nano silver on surface, nano silver cladded on aluminum particles is melted at 300° C. during being sintered to be used as a binder between aluminum and aluminum particles, which makes the microstructure very dense even the sintering is processed at a low temperature. The dense microstructure also reflects the measurement result of sheet resistance. Under a temperature held at 200˜350° C. for 15 minutes, the nano silver-clad aluminum has a very low sheet resistance. After converting this value of sheet resistance to a value of resistivity, the value of resistivity is quite close to that for a commercial nano-silver paste in the market. This means that the present invention is succeeded in the development of (micron or nano) silver-clad aluminum paste which can be sintered in the air while achieving high conductivity. This novel aluminum paste overcomes the low conductivity problem for the low-temperature copper paste processed through the low-temperature heat treatment. Besides, aluminum cladded with micron or nano silver on surface can be sintered directly in the air to achieve high conductivity quite close to that of a silver paste.

The present invention is a breakthrough for current industrial electrode materials, which can replace the electroplating copper electrode on a printed circuit board (PCB). The present invention defeats the need of expensive yellow-light development and solves the pollution problem of plating solution. Besides, the present invention replaces the metallic copper or silver electrode used in screen printing for solar substrates, LED substrates and passive component substrates, where the metallic silver electrode is expensive and the metallic copper electrode requires an expensive procedure under a reduction atmosphere.

To sum up, the present invention is a method of fabricating conductive thick-film pastes of base metals with high conductivity achieved, where the present invention processes sintering at a low or high temperature in the air; an aluminum powder is cladded with copper particles in a thickness of tens of nanometers to several microns for obtaining a copper-clad aluminum powder with high conductivity; silver can be used to reduce copper particles to clad silver particles in a thickness of tens of nanometers to several microns on the surface of aluminum particles for obtaining a silver-clad aluminum powder with high conductivity; if nano silver-clad aluminum powder is obtained, the sintering temperature can be lowered to about 350° C.; and the material cost is significantly reduced for PCB substrates or ceramic substrates.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of fabricating a conductive thick-film paste of a base metal with high conductivity achieved, comprising steps of:
(a1) dissolving a metallic copper powder to obtain a metallic copper solution;
(b1) mixing a pretreated metallic aluminum powder with said metallic copper solution to obtain a first metals-mixed solution, wherein a chemical displacement reaction is processed in said first metal mixed solution; free copper ions in said metallic copper solution move to surface of said pretreated metallic aluminum powder to obtain a layer of copper; and said layer of copper has a cladding thickness between tens of nanometers and several micrometers;
(c1) after filtering and drying said first metals-mixed solution, obtaining an aluminum powder cladded with copper; and
(d1) sintering said aluminum powder cladded with copper in the air to obtain a copper-clad aluminum thick-film paste.

2. The method according to claim 1,
wherein, in step (d1), said copper-clad aluminum thick-film paste is obtained by sintering said aluminum powder cladded with copper at a low temperature lower than 220 celsius degrees (° C.).

3. The method according to claim 2,
wherein said copper-clad aluminum thick-film paste is made of a binder, said aluminum powder cladded with copper, and an additive; said binder is a polymer resin; and said additive is selected from a group consisting of a dispersant and a rheology modifier.

4. The method according to claim 2,
wherein the resistivity of said copper-clad aluminum thick-film paste is smaller than 1×10⁻⁵ W·cm.

5. The method according to claim 2,
wherein said copper-clad aluminum thick-film paste is applied to a device selected from a group consisting of a membrane switch, a touch panel, and a radio frequency identification (RFID) device.

6. The method according to claim 1,
wherein, in step (d1), said copper-clad aluminum thick-film paste is obtained by sintering said aluminum powder cladded with copper at a high temperature lower than 600° C.

7. The method according to claim 6,
wherein said copper-clad aluminum thick-film paste is made of said aluminum powder cladded with copper, an additive, and frit; and said additive is selected from a group consisting of a dispersant and a rheology modifier.

8. The method according to claim 6,
wherein the resistivity of said copper-clad aluminum thick-film paste is smaller than 1×10⁻⁶ W·cm.

9. The method according to claim 6,
wherein said copper-clad aluminum thick-film paste is applied to a device selected from a group consisting of a passive component, a LED cooling substrate, and a silicon-based solar cell.

10. A method of fabricating a conductive thick-film paste of a base metal with high conductivity achieved, comprising steps of:
(a2) processing a corrosive wash to an aluminum powder cladded with copper;
(b2) obtaining said washed aluminum powder cladded with copper to be dissolved in ethylene glycol to obtain a copper-clad aluminum powder solution, and obtaining a metallic silver powder to be dissolved in ethylene glycol to obtain a metallic silver solution;
(c2) mixing said copper-clad aluminum powder solution with said metallic silver solution to obtain a second metals-mixed solution, wherein a chemical displacement reaction is processed in said second metals-mixed solution; free silver ions in said metallic silver solution move to surface of said washed aluminum powder cladded with copper to process reduction to obtain a layer of silver selected from a group consisting of micron silver and nano silver; and said layer of silver has a cladding thickness between tens of nanometers and several micrometers;
(d2) after filtering and drying said second metals-mixed solution, obtaining an aluminum powder cladded with silver selected from a group consisting of micron silver and nano silver; and
(e2) sintering said aluminum powder cladded with silver selected from a group consisting of micron silver and nano silver in the air to obtain a silver-clad aluminum thick-film paste.

11. The method according to claim 10,
wherein, in step (e2), said silver-clad aluminum thick-film paste is obtained by sintering said aluminum powder cladded with silver selected from a group consisting of micron silver and nano silver at a low temperature lower than 300° C.

12. The method according to claim 11,
wherein said silver-clad aluminum thick-film paste is made of a binder, said aluminum powder cladded with micron silver, and an additive; said binder is a polymer resin; and said additive is selected from a group consisting of a dispersant and a rheology modifier.

13. The method according to claim 11,
wherein said silver-clad aluminum thick-film paste is made of said aluminum powder cladded with nano silver and an additive; nano silver cladded on said aluminum powder is used as a binder; and said additive is selected from a group consisting of a dispersant and a rheology modifier.

14. The method according to claim 11,
wherein the resistivity of said silver-clad aluminum thick-film paste obtained by sintering said aluminum powder cladded with micron silver is smaller than 1×10−5 W·cm;
and the resistivity of said silver-clad aluminum thick-film paste obtained by sintering said aluminum powder cladded with nano silver is smaller than 1×10⁻⁶ W·cm.

15. The method according to claim 11,
wherein said silver-clad aluminum thick-film paste obtained by sintering said aluminum powder cladded with micron silver is applied to a device selected from a group consisting of a membrane switch, a touch panel, and an RFID device; and said silver-clad aluminum thick-film paste obtained by sintering said aluminum powder cladded with nano silver is applied to a high-powder printed circuit board, a passive component, a LED cooling substrate, and a silicon-based solar cell.

16. The method according to claim 10,
wherein, in step (e2), said silver-clad aluminum thick-film paste is obtained by sintering said aluminum powder cladded with silver selected from a group consisting of micron silver and nano silver at a high temperature lower than 600° C.

17. The method according to claim 16,
wherein said silver-clad aluminum thick-film paste is made of said aluminum powder cladded with silver, an additive, and frit; and said additive is selected from a group consisting of a dispersant and a rheology modifier.

18. The method according to claim 16,
wherein the resistivity of said silver-clad aluminum thick-film paste is smaller than 1×10⁻⁶ W·cm.

19. The method according to claim 16,
wherein said silver-clad aluminum thick-film paste is applied to a passive component, a LED cooling substrate, and a silicon-based solar cell.
